(19) United States
(12) Patent Application Publication
(10) Pub. No.: US 2025/0040258 A1
(43) Pub. Date: Jan. 30, 2025

(54) TWO-TERMINAL TANDEM SOLAR MODULE

(71) Applicant: NATIONAL UNIVERSITY OF SINGAPORE, Singapore (SG)

(72) Inventors: Jai PRAKASH, Singapore (SG); Shubham DUTTAGUPTA, Singapore (SG); Nitin NAMPALLI, Singapore (SG); Carlos Enrico Cobar, Singapore (SG)

(73) Assignee: NATIONAL UNIVERSITY OF SINGAPORE, Singapore (SG)

(21) Appl. No.: 18/715,497

(22) PCT Filed: Dec. 5, 2022
(86) PCT No.: PCT/SG2022/050883

§ 371 Date: May 31, 2024

(30) Foreign Application Priority Data
Dec. 6, 2021 (SG) 10202113508X

(51) Int. Cl. H01L 31/078; H01L 31/02; H01L 31/043; H01L 31/044

(52) U.S. Cl. CPC H01L 31/078; H01L 31/0201; H01L 31/043; H01L 31/044

(57) ABSTRACT

Disclosed is a tandem solar module and a method for forming such a module. The module includes a plurality of cell strips formed by cutting a full cell parallel to a direction of extension of a bus bar of the full cell, a plurality of strings arranged in one or more parallel sets, each string comprising two or more said cells strips interconnected end-to-end with respect to the direction of extension, and a terminal at each opposite end the one or more parallel sets.

### TECHNICAL FIELD

The present invention relates, in general terms, to solar cell layup and interconnection. More particularly, the present invention relates to the interconnection of solar cell strips to form a tandem solar module and a method of producing or fabricating a tandem solar cell.

### BACKGROUND

Standard wafer-based solar cell fabrication involves a thin slice of semiconductor, such as a crystalline silicon (c-Si), used for the fabrication of solar cells (photovoltaic cells). Standard wafer-based solar cells typically have a common and consistent spectral range tailored to absorb light for a certain period of the day. Wavelengths of light outside that spectrum is not absorbed and therefore not converted to electricity.

To increase the energy conversion efficiency of a solar cell, tandem solar cells have been more recently proposed. Tandem solar cells provide cells that work in tandem to absorb light over a broader spectral range or multiple spectral ranges. Each tandem solar cell comprises two or more sub-cells each of which is a different spectral range for light absorption.

Tandem modules cannot exhibit the same cell interconnection schemes as that used for standard c-Si based modules. For series connected cells, the large voltages of 2T tandem cells (˜1.8 V) puts additional stress on particular cells due to voltage mismatch along the series of connected cells. A mismatch can occur due to shadows while working in outdoor conditions. For perovskite cells the current response can change with changes in illumination, also causing stress variations. The reverse bias breakdown voltage of a perovskite-based solar cell is also significantly lower compared to a silicon solar cell, increasing the risk of irreversible damage to the module product in reverse bias conditions.

In conventional modules, a bypass diode is connected for every 20 or 24 cells in a series of cells. However, for tandem cells the reverse bias voltage can be as high as 40 V if 20 or 24 cells are connected in series per bypass diode. The key design considerations for tandem cell interconnections and large-size tandem module realization with two terminals output are thus: module current and voltage ratings for specific number of cells (specific size); and reverse biased behaviour of tandem cells and associated temperature rise under mismatch/shading (hotspot problem).

It would be desirable to overcome or ameliorate at least one of the above-described problems with tandem modules and/or their interconnections, or at least to provide a useful alternative.

### SUMMARY

The present invention relates to a tandem roller module comprising a plurality strings of cells connected in series along their busbars. Bypass diodes are inserted into the series to bypass one or more of the strings.

To that end, disclosed is a method of producing a tandem solar module, comprising:
forming a plurality of cell strips by cutting a full cell parallel to a direction of extension of a bus bar of the full cell;
stringing the cell strips together, end-to-end with respect to the direction of extension, to form a plurality of strings each comprising two or more cells strips;
arranging the strings in one or more parallel sets;
providing a terminal at opposite ends of the one or more parallel sets.

In some embodiments, the method may comprise method of producing a tandem solar module, comprising:
forming a plurality of cell strips by cutting a full cell parallel to a direction of extension of a bus bar of the full cell (the direction of extension);
stringing the cell strips together, end-to-end with respect to the direction of extension, to form a series comprising at least one string of cell strips; and
providing a terminal at each opposite end of the series.

As used herein, the term “direction of extension” in relation to the busbars means along the busbars or parallel to the busbars—e.g. from top of page towards bottom of page in FIG. 3a.

Arranging the strings in one or more parallel sets may comprise arranging the strings into parallel sets, the method further comprising interconnecting the parallel sets in end-to-end arrangement. Providing a terminal at opposite ends of the one or more parallel sets may comprise providing a terminal at each opposite end of the end-to-end arrangement of parallel sets.

Forming the plurality of cell strips by cutting the full cell parallel to the direction of extension, may comprise cutting the full cell such that each cell strip comprises at least one said busbar.

Stringing the cell strips into at least two strings may comprise forming each string by connecting a plurality of cell strips in series.

Assembling a plurality of the strings into a parallel set may comprise between three and 18 (e.g. six) strings in parallel.

Interconnecting the parallel sets may comprise interconnecting the sets into a series. The method may further comprise inserting at least one bypass diode between the parallel sets, or within each parallel set, the bypass diode providing a short-circuit around one or more strings. Inserting at least one bypass diode between the parallel sets may comprise inserting a bypass diode to provide a short-circuit around one of the sets. Inserting a bypass diode may comprise inserting a bypass diode for each set, the bypass diode bypassing the respective set.

The series may comprise three said parallel sets of strings.

Also disclosed is a tandem solar module comprising:
a plurality of cell strips formed by cutting a full cell parallel to a direction of extension of a bus bar of the full cell;
a plurality of strings arranged in one or more parallel sets, each string comprising two or more said cells strips interconnected end-to-end with respect to the direction of extension; and
a terminal at each opposite end the one or more parallel sets.

Each cell strip may comprise at least one said bus bar.

The strings may be arranged into parallel sets and interconnected in end-to-end arrangement. The module may comprise a said terminal at each opposite end of the end-to-end arrangement of parallel sets.

Each parallel set may comprise between three and 18 (e.g. six) strings in parallel.

The module may comprise two or more parallel sets interconnected into a series of parallel sets. The module may further comprise at least one bypass diode inserted between the parallel sets, the bypass diode providing a short-circuit around one or more strings. The bypass diode may provide a short-circuit around one of the sets. The parallel sets may be interconnected through respective bypass diodes, each bypass diode bypassing a respective said set. The series may comprise three said parallel sets of strings.

Advantageously, embodiments of the invention employ cells cut along the busbar. This maintains the power, voltage and current of the module at levels comparable to standard solar modules.

Advantageously, embodiments of the invention make use of series and parallel interconnections of cells and strings. These interconnections minimise hotspot issues during reverse biasing of cells resulting from, for example, mismatch.

Advantageously, diode placement in embodiments of the invention prevents module failure in the field (i.e. in practice) when the module is only partially shadowed.

### BRIEF DESCRIPTION OF THE DRAWINGS

Embodiments of the present invention will now be described, by way of non-limiting example, with reference to the drawings in which:

FIG. 1 schematic of a 2-terminal (2T) tandem solar cell module;

FIG. 2 is a method for fabricating a 2T tandem solar module in accordance with present teachings;

FIG. 3a shows a prior art cutting and stringing scheme for cutting a full cell into individual cells;

FIG. 3b shows the present cutting and stringing scheme for cutting a full cell into individual cells;

FIG. 4 is a schematic illustration of the proposed 2-terminal (2T) Tandem module design;

FIG. 5 is an electrical model of a 2T tandem cell;

FIG. 6 illustrates the modelled shading scenarios;

FIG. 7 shows the results of voltage of shaded cells as a simulated shading area progresses from 0% to 100% of a full cell area; and

FIG. 8 shows the results for maximum heat generated at the shaded cell in the cases indicated in FIG. 7.

### DETAILED DESCRIPTION

Described below is a tandem photovoltaic (PV) module. The interconnection of two-terminal (2T) tandem cells use a novel module design. Described herein are concepts for improving the performance, reliability and fabrication of, for example, Si/perovskite based 2T tandem modules.

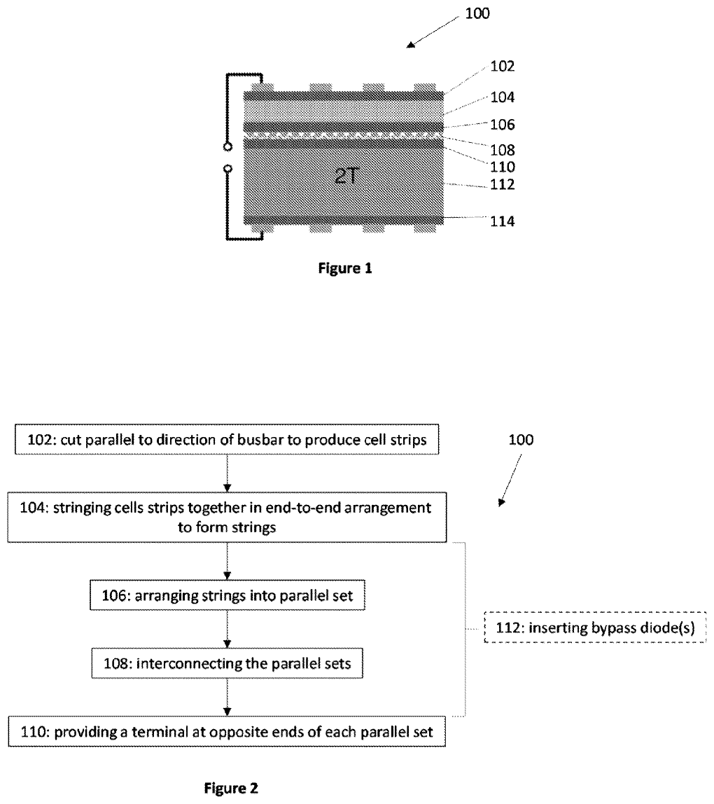

Tandem cells consist of a stack of two or more solar cells (‘sub-cells’) that are in intimate mechanical and electrical contact with each other. The sub-cells are a top sub-cell and a bottom sub-cell in the case of a two-junction tandem cell, and there may be more than two sub-cells. Each sub-cell comprises one solar cell with a photovoltaic absorber material with a specific electronic bandgap capable of generating photovoltage from a specific spectral range present in sunlight. The specific spectral range for energy conversion in each sub-cell is unique and may overlap with the spectral range of the subsequent sub-cell—“subsequent” here refers to the other cells in the stack, e.g. for each cell in a two (or more) cell stack, the spectral range is unique and potentially overlaps (but may not overlap) the spectral range of the other cell or cells (the subsequent cell or cells) in the stack. The mechanical, optical and electrical contact between sub-cells are formed using a suitable material or structure such as a transparent conductive adhesive, a tunnel junction or a recombination junction. A typical tandem solar cell consisting of two sub-cells is shown in FIG. 1.

The tandem solar cell 100 in FIG. 1 comprises two sub-cells. The first sub-cell comprises a wide bandgap absorber material 104 sandwiched between a n-type or n-doped semiconductor layer 102 and p-type or p-doped semiconductor layer 106. The second sub-cell comprises a lower or narrower bandgap absorber material 112 sandwiched between a n-type or n-doped semiconductor layer 110 and p-type or p-doped semiconductor layer 114. A recombination junction layer or layer stack 108 is sandwiched between the p-type layer 106 of the first sub-cell and the n-type layer 110 of the second sub-cell.

The differing bands of light absorbance result in the tandem cell being able to absorb, and convert to electrical energy, a broader range of wavelengths of sunlight.

The design limitations resulting from stress generation due to voltage mismatch along a series of cells limits the utility and reliability of tandem solar cells. To that end, described below are methods for fabricating a module (and the resulting module) that improve the performance, reliability and fabrication process of tandem solar modules such as Si/perovskite based 2T tandem modules.

To facilitate integration with existing systems, a design scheme described below seeks to maintain the current and voltage rating of standard modules. Cell interconnections and the cell cutting scheme are redesigned to help design a module which can be used in an existing photovoltaic (PV) system without the need to change design and layout of plant—e.g. cabling and inverter. The skilled person will understand, in view of the present teachings, that other formats of solar module (e.g. larger modules) are possible without deviating from the scope of the present disclosure.

FIG. 2 illustrates a method 100 for fabricating a two-terminal (2T) tandem solar module in accordance with present teachings. The method 100 involves (step 102) cutting a full cell parallel to the direction of extension of the busbars to produce cell strips, (step 104) the cell strips are then strung together in end-to-end arrangement to form strings that are then (step 106) arranged into one or more parallel sets. Terminals are then provided—e.g. formed or attached— at opposite ends of the one or more parallel sets per step 110. As used herein, the term “direction of extension” in relation to the busbars means parallel to the busbars, whether along or between busbars.

Where there is only a single parallel set formed at step 106, the terminals are provided at opposite ends of that parallel set. Where there are multiple parallel sets formed at step 106, the terminals may be provided at opposite ends of each parallel set or, where the parallel sets are interconnected at step 108 (e.g. into a group of parallel sets, or a series of parallel sets connected end-to-end as shown in FIG. 4), at opposite ends of the group or series of parallel sets.

In some embodiments, the module comprises bypass diodes inserted according to step 112 between strings and/or parallel sets so as to bypass one or respective strings and/or parallel sets.

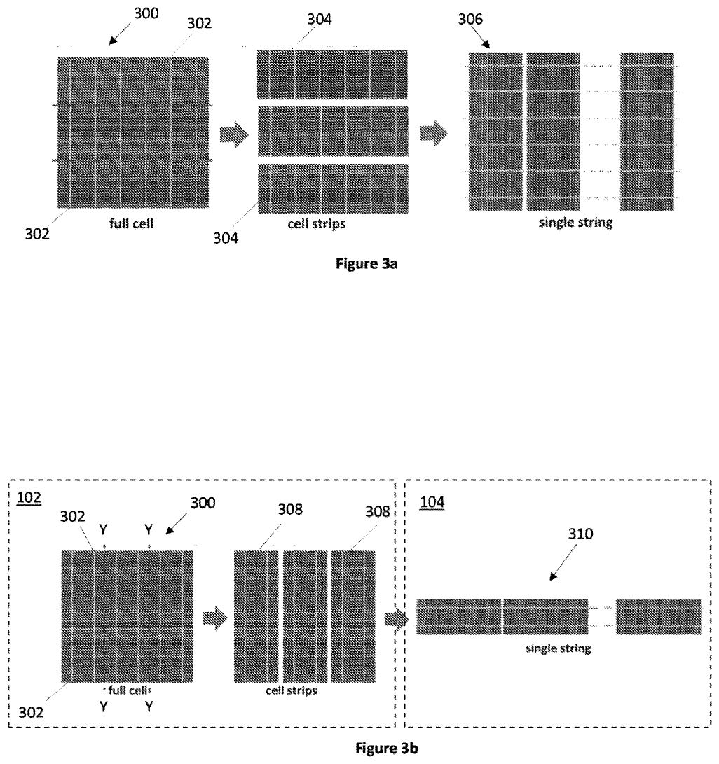

In prior art methods as shown in FIG. 3a, a full cell 300 is cut perpendicular to the busbars (some of which are indicated by reference numeral 302) in direction X, to form cell strips 304. The cell strips 304 are then rotated and strung together to form a string 306. Notably, each cell strip 302 comprises a portion of every busbar from the original fulfil 300. Consequently, each string 306 is very long and contains multiple cells connected in series, thereby generating a large string voltage.

Step 102 of the present method 100 instead involves cutting a full cell 300 parallel to the busbars 302, as shown in FIG. 3b (steps 102 and 104 of FIG. 2 are indicated in broken lines). This produces cell strips 308 each of which comprises one, or in the present embodiment to, busbars. With particular reference to FIG. 3b, each cell strip 308 comprises a full busbar or busbars from the original full cell 300, as opposed to portions of each busbar of the original full cell 300 per cell strips 304 of the prior art cutting method. Per step 104, the cell strips 308 are then rotated and strung together (i.e. interconnected) into a string 310 comprising a plurality of cell strips 308 connected in series in the direction of extension of the busbar or busbars in the cell strips 308 from which the string 310 is formed.

According to step 106, the string 310 are then arranged in parallel sets. Each parallel set comprises one or more strings, it will generally comprise two or more strings arranged in parallel. The ends of the strings in a parallel set can then be electrically connected enabling the parallel set to behave as a single electricity generating unit and to be interconnected with other components or a further parallel set per step 108. Where there are multiple parallel sets, the parallel sets may be interconnected in parallel or series (i.e. end-to-end interconnection). Per step 110, where the parallel sets are interconnected in parallel, the ends of the parallel sets can be electrically interconnected and a terminal provided at each of the two electrical interconnections of the parallel sets. Similarly per step 110, where the parallel sets are connected in series, a terminal may be provided at each opposite end of the series.

As will be appreciated, the strings 310 formed according to step 102 and 104 of method 100 may be arranged in various configurations. For illustration purposes, the present method and layout methodology will be further described with reference to a module having a 60-cell equivalent, maximum design output current of <12 A, maximum design output voltage of 50V and maximum cell-reverse biased voltage of the tandem cell that is less than the reverse breakdown voltage of the tandem cell. In particular, as shown in FIG. 3b, a full cell is cut into three cell strips parallel to (including along) the busbars. With reference to FIG. 4, the resulting module 400 is formed from strings (one of which is illustratively indicated by reference numeral 402 though exactly which cell strips 404 form a string will depend on the interconnection scheme) each comprising 10 cell strips 404, parallel sets 406, 406′ each comprising 6 strings, with a total number of 3 bypass diodes 408 in the module 400.

The definitions given above are relatively flexible. For example, a parallel set of strings is indicated with reference numeral 406 with a bypass diode 408′ disposed within the parallel set 406 for bypassing strings within parallel set 406. A further possible parallel set 406′ is also shown in FIG. 4. Bypass diodes 408′ and 408″ separates parallel set 406′ from the other two parallel sets with which it is interconnected in series—i.e. the bypass diodes 408′ and 408″ are at opposite end of parallel set 406′ rather than within the parallel set. Each diode therefore electrically bypasses one or more cell strips, strings or parallel sets from the module when the bias voltage across the bypass diode crosses the activation voltage of the bypass diode, thereby effectively short-circuiting the one or more cell strips, strings or parallel sets from the module and preventing further reverse biasing in shaded cells.

Similarly, while 10 cell strips have been used, any other number may be used depending on the application, components, conversion efficiency, and so on. The same applies to the number of strings per parallel set, the number of parallel sets (e.g. 1, two or three or more) and so on. For example, the methods disclosed herein involve assembling an optimal number of strings in parallel, with the number of strings being generally between 3 strings and up to 18 strings. For a 60-cell module, the number of strings is optimally between 4 and 6. For larger or smaller module sizes, the number of strings may be more than 6 or less than 4. Moreover, bypass diodes can be inserted at any combination of desired locations disclosed herein.

FIG. 4 shows the schematic of cell layup and bypass diodes placement. This layup and bypass diode arrangements scheme provides superior performance in terms of hot-spot behaviour under reverse-biasing due to mismatch, potentially reducing temperature increase in variation within the module 400. Notably, the module 400 is one of many various embodiments. For example, a solar module formed in accordance with present teachings may comprise a single parallel set of strings, each string comprising multiple cell strips cut parallel to the busbars and arranged in an end-to-end series. In other embodiments, the solar module may comprise two or more parallel sets of strings, each parallel set comprising one or more strings, and each string comprising one or more (and generally multiple) cell strips.

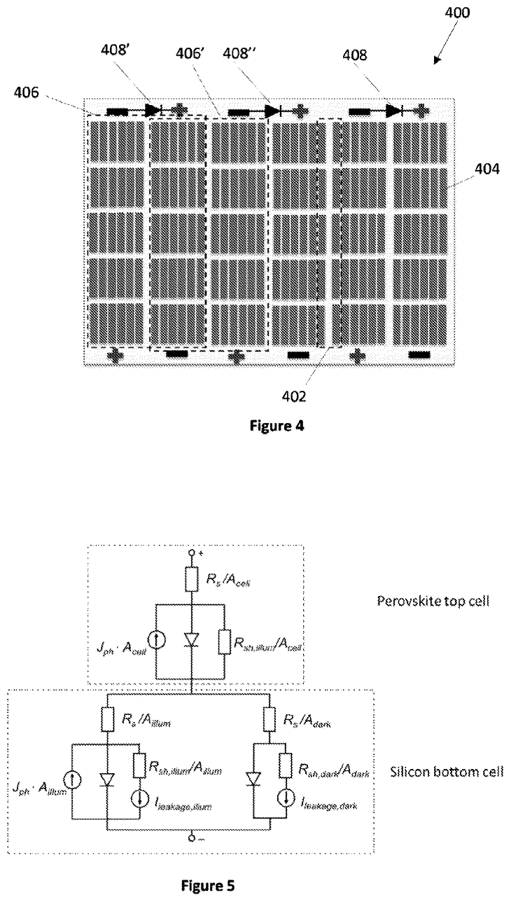

In simulated experiments, circuit simulation using LTSpice was used to model the shading response of a 2T module having a perovskite top cell and silicon bottom cell. Cell parameters are drawn from literature (Table 1), where shaded cells are modelled as shown in FIG. 5. Bishop's model for avalanche breakdown is used to model the perovskite cell while a split-cell model is used for the silicon cell to account for illumination effects on leakage current.

TABLE 1
cell parameters of silicon and perovskite top cell

| Parameter | Silicon | Perovskite |
|---|---|---|
| Jₚₕ (mA/cm²) | 20.0 | 20.0 |
| J₀ (A/cm²) | 2.4E−12 | 1.0E−15 |
| Rₛ (Ω · cm2) | 1.22E−05 | 4.97E−05 |
| n | 1.1 | 1.4 |
| Dark | | |
| V_{br}_{_{—}}_{d} (V) | −21.8 | −2 |
| a_{d} | 0.01 | 0.01 |
| m_{d} | −2 | −2 |
| Rₛₕ_{_{—}}_{d} (kΩ · cm²) | 209 | 7 |
| Light | | |
| V_{br}_{_{—}}ₗ (V) | −70000 | — |
| aₗ | 1 | — |
| mₗ | −12500 | — |
| Rₛₕ_{_{—}}ₗ (kΩ · cm²) | 20 | — |

From the 2T cell model, we expand to the module level where we compare the conventional 60 full cell interconnection to the proposed module design. A cell size of 246 cm² was chosen for full cells and 82 cm² for the ⅓^{rd} cut cells (i.e. cut as shown in FIGS. 3a and 3b).

At unshaded conditions, the two configurations produce the same power. However due to having longer strings, the conventional module produces a large open-circuit voltage (VOC) of 106 V as seen in Table 2.

TABLE 2
simulated module parameters under standard test conditions
(STC) - presently, STC refers to illumination of 1000 W/m²
(spectrum as per AMI.5G) and sample at room temperature
of 25° C.

| Parameter | 60 full-cell | Invention |
|---|---|---|
| I_{MP} (A) | 4.68 | 9.36 |
| V_{MP} (V) | 89.7 | 44.8 |
| I_{SC} (A) | 4.91 | 9.82 |
| V_{OC} (V) | 106.0 | 53.0 |
| P_{MP} (W) | 419.35 | 419.35 |

In contrast, the proposed design halves this voltage (VOC=53V) while doubling the current, thus having an output that is similar to standard modules available in the market today. This is advantageous at the system level as redesign in layout and electrical interconnection may no longer be necessary.

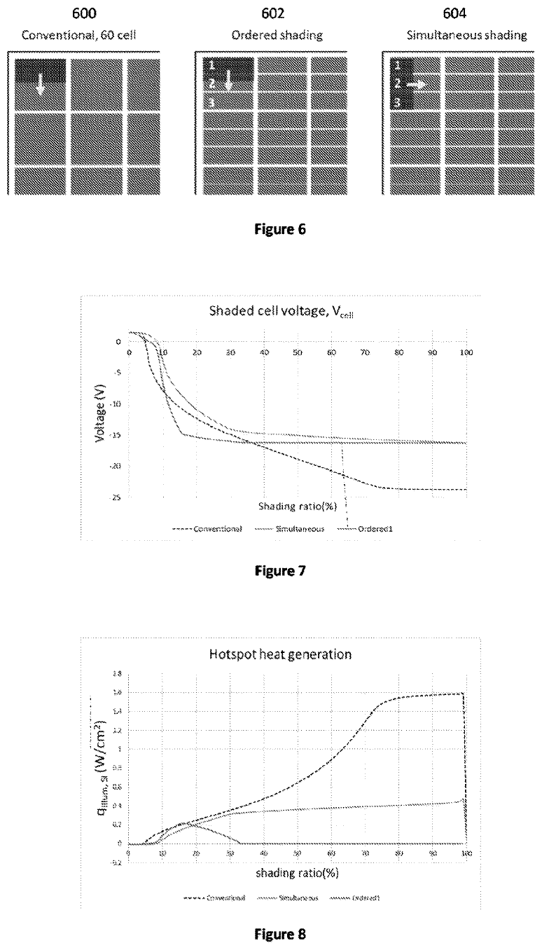

We consider shading on a single cell for the conventional 60 full-cell case. This is often the worst-case scenario as it induces the greatest current mismatch within the string. The equivalent shading scenarios for our proposed module design are also illustrated in FIG. 6, where the direction of shading affects the shading response. Thus both simultaneous and ordered shading of cut cells are considered. In particular, FIG. 6 shows conventional shading 600 of the conventional module, and ordered (602) and simultaneous (604) shading of the module formed in accordance with present teachings.

We first calculate the voltages on the cell (V_{cell}) as the shading area is increased from 0 to 100% of a full cell area. For the ordered shading case, we observe the voltage on cell 1, while for the simultaneous case all 3 cells will exhibit the same voltage response. From FIG. 7 it can be clearly observed that cells in the conventional configuration can easily reach reverse voltages of −23.6 V. This is close to the sum of perovskite and silicon breakdown voltages (V_{br,Si}+V_{br,perov}). Furthermore, the bypass diode does not activate in this scenario as the string voltage never crosses the threshold of −0.2V. This is one of the inherent disadvantages in having such high-voltage module configurations. Greater reverse biasing can potentially be reached when using cells with larger breakdown voltages. Some mono c-Si cells are known to breakdown at V_{br,Si}<−30 V.

In contrast, both simultaneous and ordered scenarios in the proposed module design only reach negative voltages of −16.3 V. This results from bypass diode activation taking place, stemming further reverse biasing. This occurs as the reduction in string length from the proposed design limits the extent to which a shaded cell may be pushed into reverse bias by other series connected cells. The difference in operating voltage translates directly into lower hotspot heating on the illuminated region, qᵢₗₗᵤₘ (W/cm²), as is seen at the silicon bottom cell where majority of the reverse biasing takes place. FIG. 8 illustrates the difference in heat generated in the hotspot region, where the conventional 60 full cell case generates almost 4 times as much heating in the silicon bottom cell near full shading. The proposed interconnection method in the module design achieves lower heating due to 1) the shorter string lengths leading to lower reverse bias voltages and quicker bypass diode activation and 2) the presence of 6 parallel strings that can compensate for the current drop caused by shading. Furthermore, the narrower ⅓^{rd} cut cells will provide better heat transport mechanics as the heat generated within the hotspot can more easily dissipate across the cell borders than in a full cell case.

Technologies disclosed herein facilitate significant improvement (i.e. reduction) in module open-circuit voltage, while maintaining good cell current and contactability resulting in improved module power output, which is one of the major drivers towards reducing levelised cost of electricity (LCOE) required for large-scale PV installation and deployment.

It will be appreciated that many further modifications and permutations of various aspects of the described embodiments are possible. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A method of producing a tandem solar module, comprising:
forming a plurality of cell strips by cutting a full cell parallel to a direction of extension of a bus bar of the full cell;
stringing the cell strips together, end-to-end with respect to the direction of extension, to form a plurality of strings each comprising two or more cells strips;
arranging the strings in one or more parallel sets;
providing a terminal at opposite ends of the one or more parallel sets.

2. The method of claim 1, wherein arranging the strings in one or more parallel sets comprises arranging the strings into parallel sets, the method further comprising interconnecting the parallel sets in end-to-end arrangement.

3. The method of claim 2, wherein providing a terminal at opposite ends of the one or more parallel sets comprises providing a terminal at each opposite end of the end-to-end arrangement of parallel sets.

4. The method of claim 1, wherein forming the plurality of cell strips by cutting the full cell parallel to the direction of extension, comprising cutting the full cell such that each cell strip comprises at least one said busbar.

5. The method of claim 1, wherein stringing the cell strips into at least two strings comprises forming each string by connecting a plurality of cell strips in series.

6. The method of claim 1, wherein assembling a plurality of the strings into a parallel set comprises assembling between three and 18 strings in parallel.

7. The method of claim 1, wherein interconnecting the parallel sets comprises interconnecting the sets into a series.

8. The method of claim 7, further comprising inserting at least one bypass diode between the parallel sets, or within each parallel set, the bypass diode providing a short-circuit around one or more strings.

9. The method of claim 8, wherein inserting at least one bypass diode between the parallel sets comprises inserting a bypass diode to provide a short-circuit around one of the sets.

10. The method of claim 9, wherein inserting a bypass diode comprises inserting a bypass diode for each set, the bypass diode bypassing the respective set.

11. The method of claim 7, wherein the series comprises at least three said parallel sets of strings.

12. A tandem solar module comprising:
a plurality of cell strips formed by cutting a full cell parallel to a direction of extension of a bus bar of the full cell;
a plurality of strings arranged in one or more parallel sets, each string comprising two or more said cells strips interconnected end-to-end with respect to the direction of extension; and
a terminal at each opposite end the one or more parallel sets.

13. The module of claim 12, wherein each cell strip comprises at least one said bus bar.

14. The module of claim 12, wherein the strings are arranged into parallel sets and interconnected in end-to-end arrangement.

15. The module of claim 14, comprising a said terminal at each opposite end of the end-to-end arrangement of parallel sets.

16. The module of claim 12, wherein each parallel set comprises between three and 18 strings in parallel.

17. The module of claim 12, comprising two or more parallel sets interconnected into a series of parallel sets.

18. The module of claim 17, further comprising at least one bypass diode inserted between the parallel sets, the bypass diode providing a short-circuit around one or more strings.

19. The module of claim 18, wherein the bypass diode provides a short-circuit around one of the sets.

20. The module of claim 19, wherein the parallel sets are interconnected through respective bypass diodes, each bypass diode bypassing a respective said set.

21. The module of claim 17, wherein the series comprises at least three said parallel sets of strings.

22. A method for producing a tandem solar module, comprising:
forming a plurality of cell strips by cutting a full cell parallel to a direction of extension of a bus bar of the full cell (the direction of extension);
stringing the cell strips together, end-to-end with respect to the direction of extension, to form a series comprising at least one string of cell strips; and
providing a terminal at each opposite end of the series.
